(19) United States
(12) Patent Application Publication
(10) Pub. No.: US 2012/0257133 A1
(43) Pub. Date: Oct. 11, 2012

(54) MANUFACTURING METHOD OF LIQUID CRYSTAL DISPLAY DEVICE AND LIQUID CRYSTAL DISPLAY DEVICE

(75) Inventors: Kenji Tsuchiya, Narashino (JP); Eisaku Hazawa, Mobara (JP); Hiroaki Yamamoto, Mobara (JP)

(73) Assignee: Hitachi Displays, Ltd.

(21) Appl. No.: 13/433,394

(22) Filed: Mar. 29, 2012

(30) Foreign Application Priority Data
Apr. 11, 2011 (JP) 2011-087388

(51) Int. Cl. G02F 1/136; H01L 33/08

(52) U.S. Cl. 349/43; 438/30; 257/E33.012

(57) ABSTRACT

A manufacturing method of liquid crystal display device is provided that can increase manufacturing yield by reducing the number of layers and manufacturing costs and by preventing backlight lamp failure.

In the manufacturing method of the device, a semiconductor layer 4 and a pixel electrode 5 are formed on a gate insulating film 3. Subsequently, a drain electrode electrically interconnecting the semiconductor layer 4 and the pixel electrode 5 of the pixel region A is formed by overlaying a flat solid conductive film on the substrate, followed by removing the conductive film with the use of a photoresist pattern as a mask, while exposing the semiconductor layer 4 at the pixel region A and the adjacent area C. The semiconductor layer 4 at the pixel region A is etched by using, as an index, an etching amount of the semiconductor layer 4 at the adjacent area.

### CLAIM PRIORITY

The present application claims priority from Japanese patent application JP 2011-087388 filed on Apr. 11, 2011, the content of which is hereby incorporated by reference into this application.

### BACKGROUND OF THE INVENTION

1. Field of the Invention

The present invention relates to a manufacturing method of horizontal electric field type liquid crystal display device and a liquid crystal display device.

2. Description of the Related Art

A liquid crystal display panel for use in a liquid crystal display device includes: a TFT substrate on which pixels, each including a pixel electrode, a thin-film transistor (TFT) and the like, are arranged in a matrix form; a counter substrate opposed to the TFT substrate and formed with a color filter and the like in corresponding relation to the pixel electrode of the TFT substrate; and liquid crystal sealed between the TFT substrate and the counter substrate. An image is formed by controlling transmission of light through liquid crystal molecules on a per pixel basis.

The liquid crystal display device has a flat and lightweight structure and hence, finds more and more applications in various fields. Compact size liquid crystal display devices are widely used in cell phones, DSCs (Digital Still Cameras) and the like. Viewing angle characteristics are important in the liquid crystal display devices. The viewing angle characteristics refer to a phenomenon that the image is varied in luminance or chromaticity depending upon whether it is viewed from front or at oblique angle. An IPS (In-Plane Switching) type device capable of operating the liquid crystal molecules by applying a horizontal electric field exhibits excellent viewing angle characteristics (see, for example, Japanese Patent Application Laid-Open Publication No. 2010-8999).

There are known various types of IPS liquid crystal display devices. An increased transmittance can be achieved by a type, for example, wherein a common electrode or pixel electrode is formed of a flat solid layer and the pixel electrode or common electrode in an interdigital form is laid thereon with an insulating film interposed therebetween and wherein the liquid crystal molecules are rotated by an electric field induced between the pixel electrode and the common electrode. Hence, this type of device is predominant now.

The IPS device of the above-described type is conventionally manufactured by the steps of: first forming TFTs, overlaying a passivation film on the TFTs, and forming thereon the above-described common electrode (or pixel electrodes), an insulating film, the pixel electrodes (or the common electrode) and the like. However, it has become a common practice to reduce the number of layers on the TFT substrate, such as conductive film and insulating film, in order to meet a demand for reducing manufacturing costs.

### SUMMARY OF THE INVENTION

FIGS. 1A to 1F is a set of sectional views illustrating a manufacturing method and configuration of a novel TFT substrate contemplated by the inventors addressing the problem of the conventional IPS devices or of how to reduce the number of layers on the TFT substrate, such as the conductive film and insulating film. FIG. 4 is a plan view of the TFT substrate.

As shown in FIG. 4, the TFT substrate includes: a substrate 1; a product zone (liquid crystal display device zone) 12; a product pixel zone 13; a product wiring zone 14; and a thickness TEG zone 17. The figure shows two product zones.

Now, description is made on a manufacturing method of this TFT substrate. As shown in FIG. 1A, a gate electrode 2 is formed on the substrate 1 formed of glass (gate electrode forming step). The gate electrode 2 has a laminated structure, for example, wherein a layer of Mo (molybdenum) or a compound or alloy thereof is formed on a layer of Al (aluminum) or a compound or alloy thereof.

Subsequently, as shown in FIG. 1B, a gate insulating film 3 of SiN (silicon nitride) is overlaid on the substrate 1 by a CVD process, the substrate on which the gate electrode 2 is formed. Further, a semiconductor layer 4 is formed on the gate insulating film 3 at place above the gate electrode 2 (gate insulating film forming step, semiconductor layer forming step). As the semiconductor layer 4, a-Si film is formed by CVD process. A predetermined area of this semiconductor layer 4 defines a channel layer of the TFT.

Next, as shown in FIG. 1C, a flat solid ITO film is overlaid on the substrate 1 formed with the semiconductor layer 4 and then is photolithographically patterned so as to remove the ITO film on the semiconductor layer 4 thereby forming a pixel electrode 5 (pixel electrode forming step).

Subsequently, as shown in FIG. 1D, a flat solid layer of Mo film or of multilayer' film including an Al film sandwiched between Al-containing Mo films or Mo films is overlaid on the substrate 1 formed with the semiconductor layer 4 and the pixel electrode 5. Subsequently, a photolithography process using a photoresist film 7 as an etching mask is performed for patterning structures where the semiconductor layer and pixel electrode are exposed at predetermined areas thereof, respectively, while the Mo film or the like is allowed to extend on the semiconductor layer 4 and the pixel electrode thereby defining a drain electrode 6 (drain electrode forming step). In the meantime, the exposed area of the semiconductor layer 4 is etched to form a channel (channel etching step 8). The semiconductor layer 4 is etched using a reaction gas containing fluorine such as SF₆ or CF₄. The pixel electrode 5 is partially overlapped with the drain electrode 6 so that the pixel electrode 5 and the drain electrode 6 are electrically connected with each other. An unillustrated n+Si layer is interposed between the semiconductor layer 4 and the drain electrode 6 such that the semiconductor layer is in ohmic contact with the drain electrode.

Next, as shown in FIG. 1E, an insulating film (passivation film) 9 is overlaid on the semiconductor layer 4 with the etched channel, the pixel electrode 5, the drain electrode 6 and the like (insulating film forming step). This insulating film 9 is an SiN film formed by CVD process.

Next, as shown in FIG. 1F, a common electrode (a common electrode above the pixel electrode 5 is in the interdigital form) is formed of ITO film (common electrode forming step). It is noted that although the passivation film 9 is fundamentally formed for the purpose of protection of TFTs, the passivation film of FIG. 1F also serves as an insulating film between the common electrode 10 and the pixel electrode 5.

Subsequently, the liquid crystal display device is completed through steps which include: (i) bonding together the TFT substrate and the counter substrate formed with the color filter and the like; (ii) filling liquid crystal; (iii) cutting the bonded substrates; (iv) mounting drive circuits; (v) assembling a backlight; and the like. It is noted that the order of the above steps (i) to (iii) is not specified.

It is confirmed that the TFT substrate manufactured by the above-described steps dispenses with the steps of forming and processing the insulating film between the drain electrode and the pixel electrode and hence, can achieve a greater cost reduction than the conventional device having the IPS configuration.

Unfortunately, however, further study revealed a fact that a liquid crystal display device employing the TFT substrate manufactured by the above-described process may suffer backlight lamp failure.

In view of the foregoing, the invention seeks to provide a manufacturing method of liquid crystal display device that is adapted to achieve an increased manufacturing yield by reducing the number of layers and the manufacturing costs and by preventing the backlight lamp failure as well as to provide a reliable liquid crystal display device.

According to one aspect of the invention for achieving the above object, a manufacturing method of liquid crystal display device comprises: a first step of forming a first semiconductor layer at a first region of a substrate and a second semiconductor layer at a second region of the substrate; a second step of forming a first electrode at the first region in spaced relation with the first semiconductor layer and a second electrode at the second region in spaced relation with the second semiconductor layer; a third step of forming a third electrode electrically interconnecting the first semiconductor layer and the first electrode of the first region and also exposing the first semiconductor layer and the second semiconductor layer; and a fourth step of etching the exposed first semiconductor layer using an etching amount of the second semiconductor layer as an index.

According to another aspect of the invention, a liquid crystal display device comprises a pixel region defined by a first region on a substrate, wherein disposed at the pixel region are a gate electrode; a gate insulating film overlaid on the gate electrode; a semiconductor layer formed on the gate insulating film overlaid on the gate electrode; a pixel electrode spaced away from the semiconductor layer; a drain electrode extended on the semiconductor layer and the pixel electrode for electrically interconnecting the semiconductor layer and the pixel electrode; and a common electrode formed upwardly of the pixel electrode, and wherein at a second region on the substrate, an electrode is formed at the same time as the pixel electrode and from the same material as the pixel electrode.

According to the invention, the drain electrode is formed at the pixel region after the formation of the pixel electrode, which is also formed in the vicinity of the thickness TEG. Thus, the invention can offer the manufacturing method of liquid crystal display device that is adapted to increase the manufacturing yield by reducing the number of layers and the manufacturing costs and by preventing the backlight lamp failure. The invention can also offer the reliable liquid crystal display device.

### BRIEF DESCRIPTION OF THE DRAWINGS

FIGS. 1A-1F are a set of schematic sectional views showing a manufacturing process performed on a pixel region of a TFT substrate of a liquid crystal display device for illustrating the results of study regarding the invention, FIG. 1A showing a step of forming a gate electrode; FIG. 1B showing a step of forming a gate insulating film and semiconductor layer; FIG. 1C showing a step of forming a pixel electrode; FIG. 1D showing a step of forming a drain electrode and etching a channel; FIG. 1E showing a step of forming an insulating film; and FIG. 1F showing a step of forming a common electrode;

FIGS. 2A-2F are a set of schematic sectional views showing the manufacturing process performed on the vicinity of a thickness TEG of the TFT substrate of the liquid crystal display device for illustrating the results of the study regarding the invention, FIG. 2A showing a step of forming the gate electrode; FIG. 2B showing a step of forming the gate insulating film and semiconductor layer; FIG. 2C showing a step of forming the pixel electrode; FIG. 2D showing a step of forming the drain electrode and etching the channel; FIG. 2E showing a step of forming the insulating film; and FIG. 2F showing a step of forming the common electrode;

FIGS. 3A-3F are a set of schematic sectional views showing a manufacturing process performed on the vicinity of a thickness TEG of a TFT substrate of a liquid crystal display device according to a first embodiment of the invention, FIG. 3A showing a step of forming a gate electrode; FIG. 3B showing a step of forming a gate insulating film and semiconductor layer; FIG. 3C showing a step of forming a pixel electrode; FIG. 3D showing a step of forming a drain electrode and etching a channel; FIG. 3E showing a step of forming an insulating film; and FIG. 3F showing a step of forming a common electrode;

FIG. 4 is a schematic plan view of the TFT substrate of the liquid crystal display device for illustrating the results of the study regarding the invention;

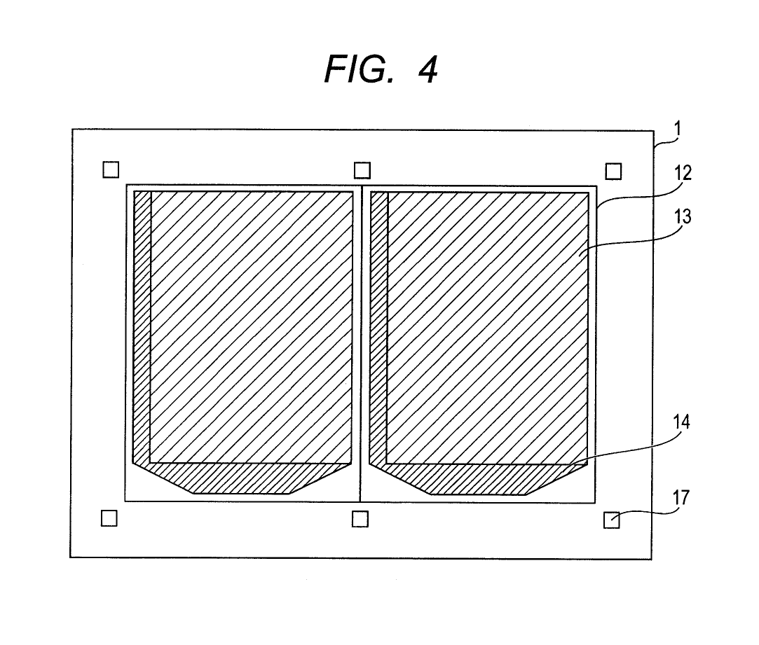

FIG. 5 is a schematic plan view of the TFT substrate of the liquid crystal display device according to the first embodiment of the invention; and

FIGS. 6A-6C are a set of schematic sectional views of the TFT substrate for illustrating how the components are etched in the channel etching step, FIG. 6A showing the pixel region including a transistor (TFT); FIG. 6B showing an adjacent area of the thickness TEG (inclusive) where the pixel electrode is not formed; and FIG. 6C showing the adjacent area of the thickness TEG (inclusive) where the pixel electrode is formed.

### DETAILED DESCRIPTION OF THE PREFERRED EMBODIMENTS

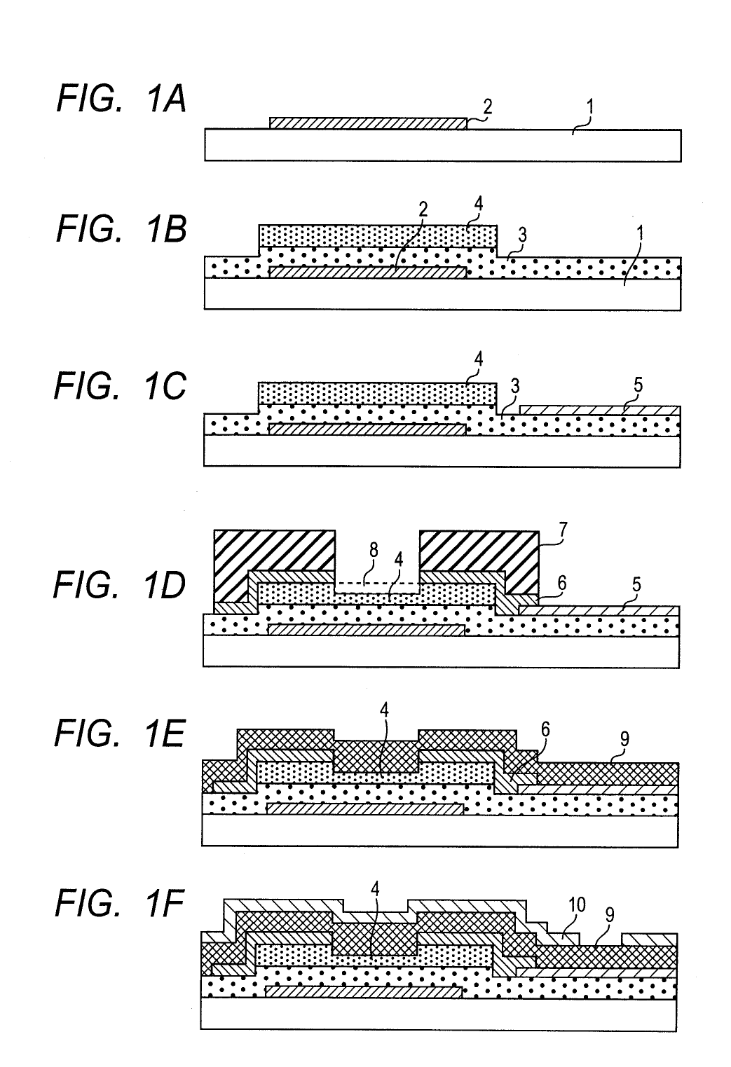

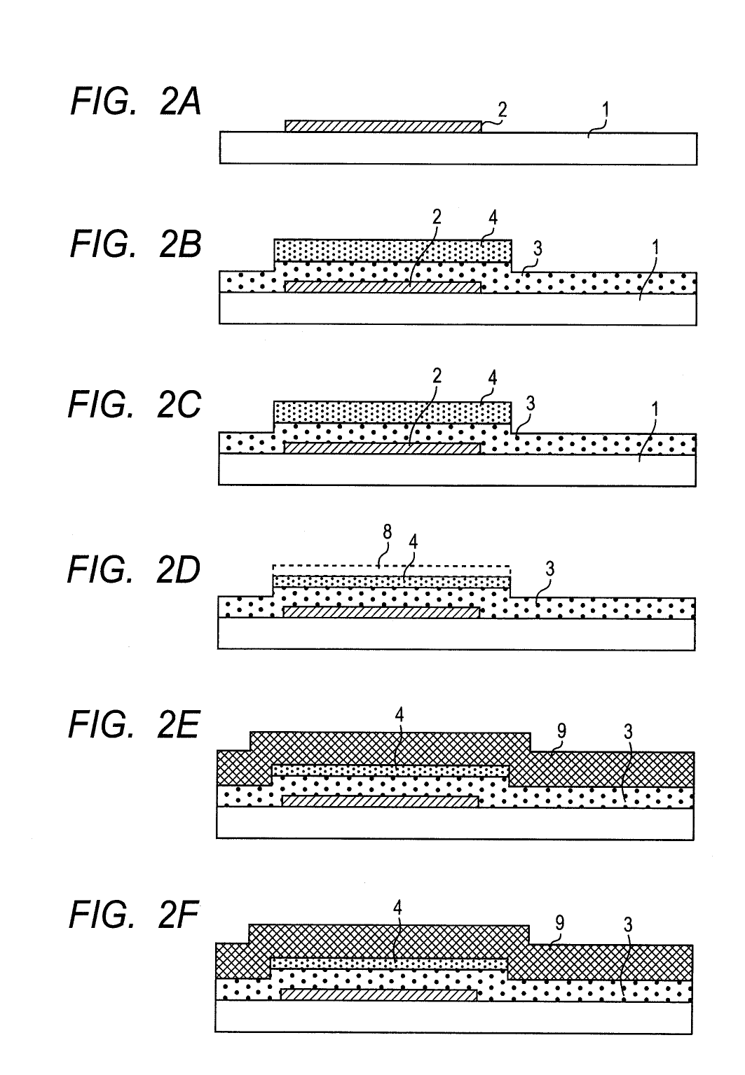

The inventors made a close study on the cause of the backlight lamp failure occurred at the TFT substrate of the liquid crystal display device manufactured by the process shown in FIGS. 1A to 1F. The inventors have found that the semiconductor layer 4 was etched to an undue depth in the channel etching step. On the other hand, abnormal etching was not observed at the thickness TEG giving an index of channel etching amount for the pixel region. Therefore, the inventors examined the manufacturing process performed on the thickness TEG. FIGS. 2A to 2F are a set of schematic sectional views showing the manufacturing process performed on the vicinity of the thickness TEG. In a gate electrode forming step shown in FIG. 2A, a gate insulating film and semiconductor layer forming step shown in FIG. 2B and an insulating film forming step shown in FIG. 2E, the respective components are formed just as shown in FIG. 1A, FIG. 1B and FIG. 1E. However, the pixel electrode forming step omits the formation of the pixel electrode at an area shown in FIG. 2C while the common electrode forming step omits the formation of the common electrode at an area shown in FIG. 2F. Particularly, the pixel electrode is not formed at the area shown in FIG. 2C. In the channel etching process, therefore, the semiconductor layer 4, the resist and the pixel electrode 5 at the pixel region are exposed to an etching gas, as shown in FIG. 1D, whereas the semiconductor layer 4 and the gate insulating film in the vicinity of the thickness TEG are exposed to the etching gas, as shown in FIG. 2D. The materials of these components were examined for resistance to the etching gas. The results indicated that the resist used as the etching mask and ITO forming the pixel electrode 5 had high resistance to the etching gas. In the step shown in FIG. 1D, the etching reaction is supply-limited. Hence, an excess etching gas is produced to accelerate the channel etching process at the pixel region where an etched material accounts for a small area. In the vicinity of the thickness TEG where the etched material accounts for a large area, on the other hand, etching rate is different (lower) than that at the pixel region. It is concluded that an etching amount of the semiconductor layer at the pixel region is unduly increased in a case where an etching rate for the thickness TEG is used as the index of etching amount.

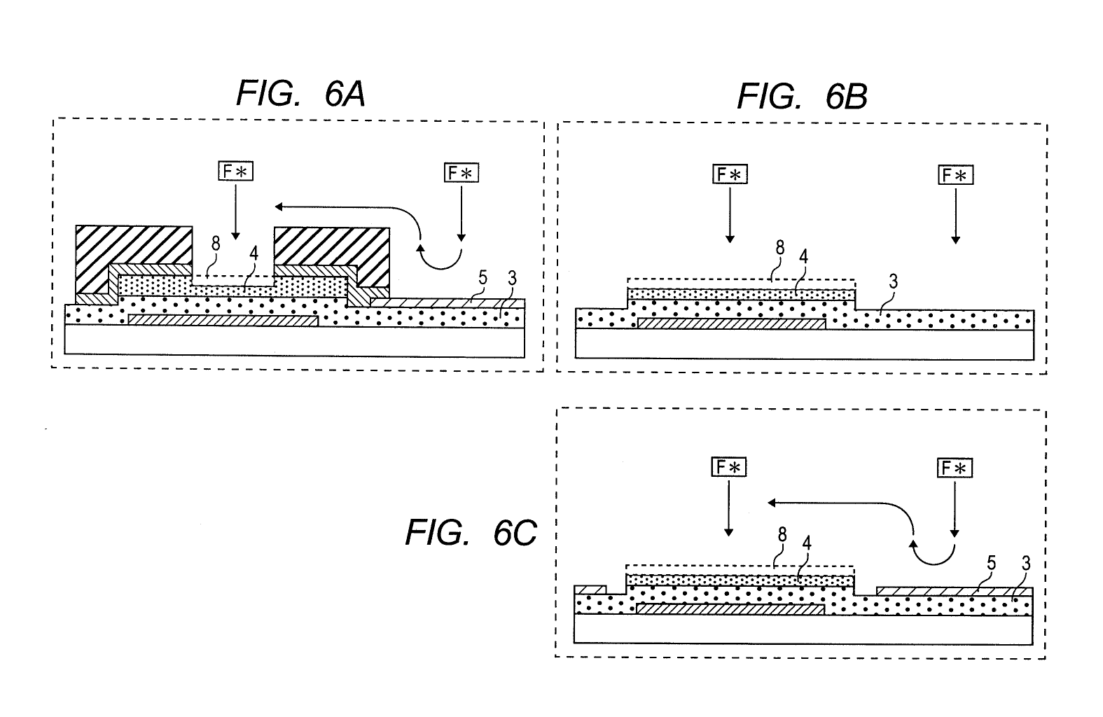

A more detailed description is made with reference to FIGS. 6A to 6C. FIGS. 6A to 6C are a set of schematic sectional views of the TFT substrate for illustrating how the components are etched in the channel etching step, FIG. 6A showing the pixel region including a transistor (TFT); FIG. 6B showing an adjacent area of the thickness TEG (inclusive) where the pixel electrode is not formed; and FIG. 6C showing the adjacent area of the thickness TEG (inclusive) where the pixel electrode is formed. In the channel etching step at the pixel region as shown in FIG. 6A, the etching gas (F*) is supplied to the overall area of the pixel electrode. However, the etching gas over the pixel electrode 5 and the resist film is not consumed so as to be supplied onto the semiconductor layer 4. Hence, the etching of the semiconductor layer 4 is accelerated to result in unduly deep etching. In the vicinity of the thickness TEG as shown in FIG. 6B, on the other hand, the etching gas (F*) is supplied to the overall adjacent area of the thickness TEG where the supplied gas is consumed. Therefore, the etching rate at this area is different (lower) than that at the pixel region. The inventors contemplated how to etch equally the semiconductor layer 4 at the pixel region and the semiconductor layer 4 at the adjacent area of the thickness TEG. The inventors found that this purpose can be accomplished by covering the gate insulating film 3 adjacent to the thickness TEG with the pixel electrode 5 for suppressing the consumption of the etching gas (F*) over the gate insulating film 3, as shown in FIG. 6C, whereby the adjacent area of the thickness TEG and the pixel region are etched under the same conditions.

The invention has been accomplished based the above findings and is characterized in that the ITO film is disposed not only on the pixel region but also on the vicinity of the thickness TEG so that the area ratios of etched films at the pixel region and in the vicinity of the thickness TEG are adjusted in the channel etching step.

The invention is described in detail as below with reference to an example thereof.

### First Embodiment

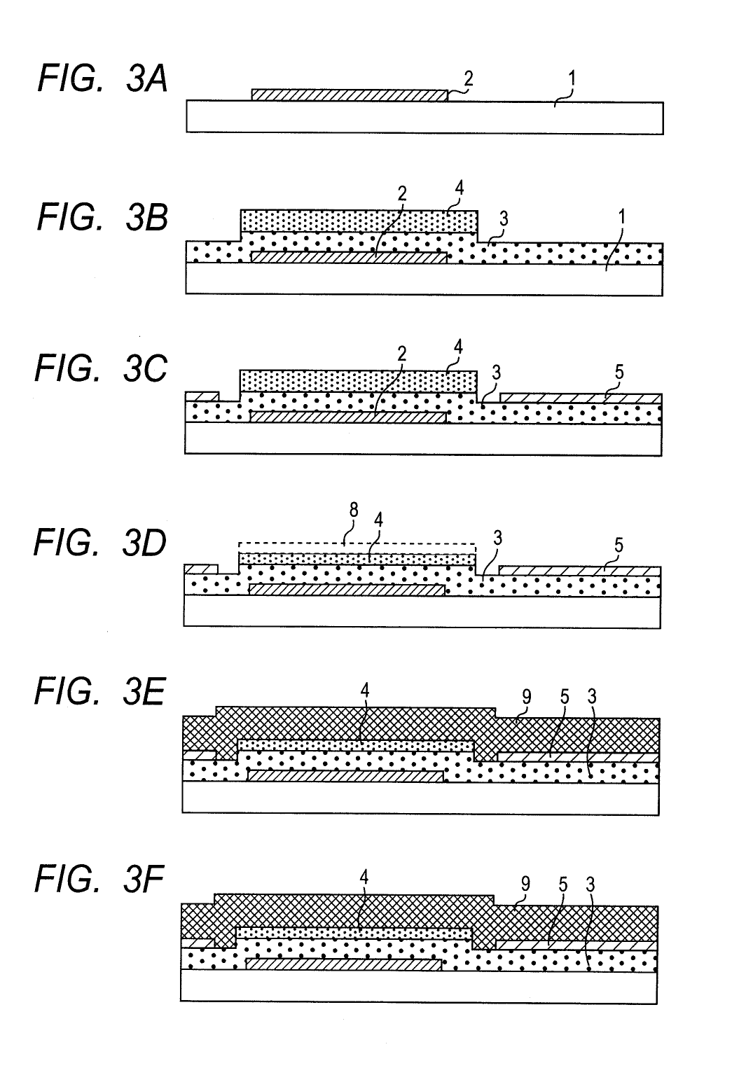

A first embodiment of the invention is described principally with reference to FIGS. 3A to 3F. FIGS. 3A to 3F are a set of schematic sectional views showing a manufacturing process performed on the vicinity of the thickness TEG of the TFT substrate of the liquid crystal display device, FIG. 3A showing the gate electrode forming step; FIG. 3B showing the gate insulating film and semiconductor layer forming step; FIG. 3C showing the pixel electrode forming step; FIG. 3D showing the drain electrode forming and channel etching step; FIG. 3E showing the insulating film forming step; and FIG. 3F showing the common electrode forming step. It is noted that like reference characters in FIGS. 1A to 1F and FIGS. 3A to 3F refer to the corresponding components, which are formed simultaneously from the same material.

First, the gate electrode 2 was formed at a thickness TEG zone on the glass substrate 1 (FIG. 3A). The gate electrode 2 comprises a dual layer including a bottom layer of AlNd alloy film having a thickness of 200 nm and a top layer of MoCr alloy film having a thickness of 40 nm. The MoCr alloy film can prevent reaction of the AlNd alloy with ITO when, for example, the AlNd alloy is used for other applications (terminal and the like).

Next, the gate insulating film 3 was overlaid on the glass substrate 1 formed with the gate electrode 2, and the semiconductor layer 4 was formed on the gate insulating film at an area above the gate electrode 2 of the thickness TEG zone (FIG. 3B). The gate insulating film 3 comprises a 350 nm thick silicon nitride (SiN) film formed by a Chemical Vapor Deposition (CVD) process. The semiconductor layer 4 comprises a 150 nm thick amorphous silicon (a-Si) film formed by the CVD process followed by photolithographic patterning using a positive resist.

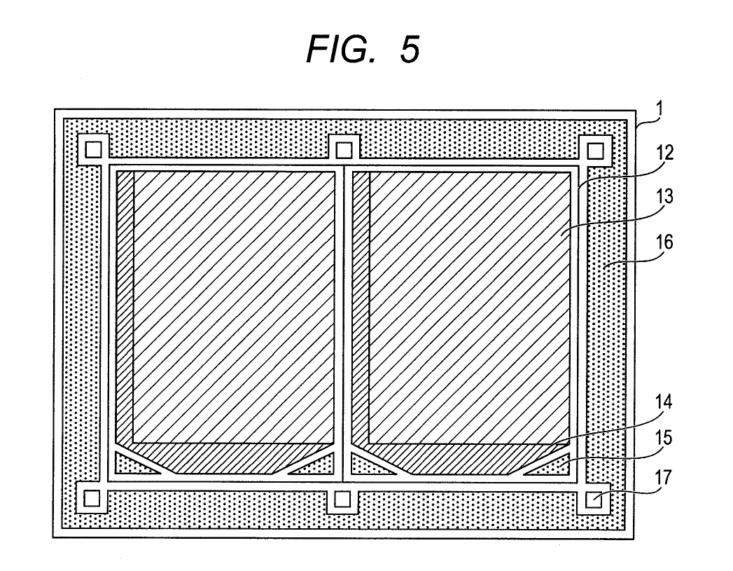

Subsequently, the pixel electrode 5 was formed in the vicinity of the thickness TEG zone on the substrate, which was formed with the semiconductor layer, in a manner that the pixel electrode was spaced away from the semiconductor layer 4 (FIG. 3C). The pixel electrode 5 was formed by the steps of forming a flat solid layer in a target thickness of 77 nm, followed by photolithographic patterning. The layout and area of the pixel electrode to be patterned are defined in a manner such that an etching (channel etching) amount of the semiconductor layer 4 at the pixel region is equal to an etching amount of the semiconductor layer 4 at the thickness TEG zone. The area and layout of the pixel electrode may be experimentally determined or otherwise, determined through simulations using different types of etching gases in different concentrations and different materials etched at different rates. FIG. 5 is a plan view showing the TFT substrate where the pixel electrode is disposed in the vicinity of the thickness TEG. Examples of the area to dispose the pixel electrode adjacent to the thickness TEG include an exemplary pattern layout inside product area 15 and an exemplary pattern layout outside product area 16, as shown in FIG. 5. In the case of the exemplary pattern layout inside product area 15, a noise reduction effect is obtained by electrically interconnecting the pixel electrode disposed in this area and the common electrode. It is desirable from the standpoint of prevention of foreign substance entry that the pixel electrode is not disposed at a cutting portion between products.

After the drain electrode was formed on the substrate formed with the pixel electrode, the channel etching was performed (FIG. 3D). According to the embodiment, a flat solid Mo film was formed and then, photolithography using the positive resist was performed to completely remove the Mo film on the thickness TEG zone and the adjacent area thereof. Just as at the pixel region, however, the thickness TEG may also be exposed together with the resist film used for the patterning of the drain electrode. In this case, this resist film serves as a mask against etching and hence, the resist film adjacent to the thickness TEG may also be used as an alternative to the pixel electrode. The channel etching was performed using SF₆ gas and the resist pattern for drain electrode formation as it was. In this process, an etching amount of the semiconductor layer 4 at the pixel region was determined with reference to an etching amount of the semiconductor layer 4 at the thickness TEG. While the embodiment used SF₆ gas as the etching gas, any fluorine-containing gas is usable.

Subsequently, a flat solid insulating film 9 was overlaid on the substrate with etched channel (FIG. 3E). The insulating film 9 was a 500 nm thick SiN film formed by CVD. This insulating film also functions as the passivation film for TFT protection.

Subsequently, the common electrode was formed on the substrate with the insulating film overlaid thereon (FIG. 3F). In this embodiment, a flat solid ITO film for the common electrode was formed and then, the ITO film on the thickness TEG and the adjacent area thereof was completely removed.

Subsequently, the liquid crystal display device was fabricated by performing the steps of: (i) bonding the TFT substrate with a counter substrate formed with a color filter and the like; (ii) filling liquid crystal; (iii) cutting the bonded substrates; (iv) mounting drive circuits; and (v) assembling backlight and the like.

The liquid crystal display device manufactured according to the above embodiment was evaluated. The results indicate that the backlight lamp failure is reduced as a result of the prevention of abnormal etching of the channel (semiconductor layer). Furthermore, the liquid crystal display device can achieve an increased reliability.

As described above, the embodiment can provide the manufacturing method of liquid crystal display device that is adapted to increase the manufacturing yield by reducing the number of layers and the manufacturing costs and by preventing the backlight lamp failure, as well as the liquid crystal display device featuring high reliability. Furthermore, the embodiment provides for noise reduction by disposing the pixel electrode for etching amount adjustment in the product area.

1. A manufacturing method of liquid crystal display device comprising:
a first step of forming a first semiconductor layer at a first region of a substrate and a second semiconductor layer at a second region of the substrate;
a second step of forming a first electrode at the first region in spaced relation to the first semiconductor layer and a second electrode at the second region in spaced relation to the second semiconductor layer;
a third step of forming a third electrode electrically interconnecting the first semiconductor layer and the first electrode of the first region and also exposing the first semiconductor layer and the second semiconductor layer; and
a fourth step of etching the exposed first semiconductor layer using an etching amount of the second semiconductor layer as an index.

2. A manufacturing method of liquid crystal display device comprising:
a gate electrode forming step of forming a first gate electrode at a pixel region of a glass substrate and a second gate electrode at a thickness TEG zone of the glass substrate;
a gate insulating film forming step of overlaying a gate insulating film on the glass substrate formed with the first and second gate electrodes;
a semiconductor layer forming step of forming a first semiconductor layer on the gate insulating film formed with the first gate electrode of the pixel region, and a second semiconductor layer on the gate insulating film formed with the second gate electrode of the thickness TEG zone;
a pixel electrode forming step of forming a first pixel electrode on the gate insulating film of the pixel region in spaced relation to the first semiconductor layer, and forming a second pixel electrode on the gate insulating film in the vicinity of the thickness TEG zone in spaced relation to the second semiconductor layer;
a drain electrode forming step of forming a drain electrode electrically interconnecting the first semiconductor layer and the first pixel electrode of the pixel region by overlaying a flat solid conductive film on the glass substrate, followed by removing the conductive film with the use of a photoresist pattern as a mask while exposing the first semiconductor layer and the second semiconductor layer;
a channel etching step of etching the exposed first semiconductor layer by continuously using the photoresist pattern as the mask and by using an etching amount of the second semiconductor layer as an index;
an insulating film forming step of subsequently overlaying an insulating film on the glass substrate; and
a common electrode forming step of forming a common electrode on the insulating film on the first pixel electrode.

3. The manufacturing method of liquid crystal display device according to claim 1, wherein the first and second semiconductor layers comprise an amorphous silicon layer.

4. The manufacturing method of liquid crystal display device according to claim 1, wherein the first and second electrodes comprise an ITO electrode.

5. The manufacturing method of liquid crystal display device according to claim 1, wherein the area and position of the second electrode formed at the second region are defined in a manner that the etching amount of the first semiconductor layer is equal to that of the second semiconductor layer in the fourth step.

6. The manufacturing method of liquid crystal display device according to claim 2, wherein the conductive film comprises a Mo film or a multilayer film including an Al film sandwiched between Mo films or Al-containing Mo films.

7. The manufacturing method of liquid crystal display device according to claim 2, wherein the first and second semiconductor layers comprise an amorphous silicon layer and the first and second pixel electrodes comprise an ITO electrode.

8. A liquid crystal display device comprising a pixel region defined by a first region on a substrate,
wherein disposed at the pixel region are a gate electrode; a gate insulating film overlaid on the gate electrode; a semiconductor layer formed on the gate insulating film overlaid on the gate electrode; a pixel electrode spaced away from the semiconductor layer; a drain electrode extended on the semiconductor layer and the pixel electrode for electrically interconnecting the semiconductor layer and the pixel electrode; and a common electrode formed upwardly of the pixel electrode, and
wherein at a second region on the substrate, an electrode is formed at the same time as the pixel electrode and from the same material as the pixel electrode.

9. The liquid crystal display device according to claim 8, wherein the gate insulating film is a silicon nitride film, the semiconductor layer is an amorphous silicon layer and the pixel electrode is an ITO electrode.
